(19) United States
(12) Patent Application Publication
(10) Pub. No.: US 2025/0035817 A1
(43) Pub. Date: Jan. 30, 2025

(54) Method For Predicting Solar Power Generation Considering Cloud Cover Prediction Information

(71) Applicant: SI Analytics Co., Ltd., Daejeon (KR)

(72) Inventors: Yeji CHOI, Sejong-si (KR); Eunbin CHO, Daejeon (KR)

(73) Assignee: SI Analytics Co., Ltd., Daejeon (KR)

(21) Appl. No.: 18/769,228

(22) Filed: Jul. 10, 2024

(30) Foreign Application Priority Data
Jul. 28, 2023 (KR) 10-2023-0098919

(51) Int. Cl. G01W 1/10; G06V 10/764; G06V 20/13

(52) U.S. Cl. CPC G01W 1/10; G06V 10/764; G06V 20/13

(57) ABSTRACT

According to an exemplary embodiment of the present disclosure, a method for predicting a solar radiation amount by using a solar radiation amount prediction model, which is performed by a computing device may include: inputting weather information into a solar radiation amount prediction model performing time series prediction; additionally inputting cloud cover prediction information into the solar radiation amount prediction model; and predicting a solar radiation amount based on the weather information and the cloud cover prediction information by using the solar radiation amount prediction model.

### CROSS-REFERENCE TO RELATED APPLICATIONS

This application claims priority to and the benefit of Korean Patent Application No. 10-2023-0098919 filed in the Korean Intellectual Property Office on Jul. 28, 2023, the entire contents of which are incorporated herein by reference.

### TECHNICAL FIELD

The present disclosure relates to a method for predicting solar power generation, and more particularly, to a method for predicting solar power generation considering cloud cover prediction information based on a satellite image.

### BACKGROUND ART

In recent years, an interest in renewable energy has increased due to climate change and increasing energy demand. In particular, a weight occupied by solar power is rapidly increasing worldwide.

The solar power generation is variable renewable energy (VRE) in which energy production is irregularly changed by natural factors. In particular, a ramping phenomenon in which power supply is unstable due to rapid variations in renewable energy generation, is a factor in economic loss. Therefore, accurate power generation prediction is required for stable power operation.

Although the amount of solar radiation is a weather element which exerts the most influential effect on the prediction of solar power generation, the amount of solar radiation cannot be provided through the weather forecast of the meteorological agency. Clouds are an important weather element that greatly affects the amount of solar radiation, and cloud cover forecast data can be received from the Meteorological Agency. Therefore, research is being actively conducted to predict the solar power generation and the amount of solar radiation using a cloud cover.

Currently, in respect to the cloud cover forecast data provided by the meteorological agency, data produced by the numerical forecast model is processed as a forecasting element that meets the forecast definition of the Meteorological Agency, and provided as a sky state. The sky state means expressing a degree at which the cloud covers the sky by clear, cloudy, and overcast. In respect to such a sky state, only limited future cloud covers classified into 3 categories can be obtained.

Synoptic weather observation means a ground observation which is carried out at the same time at all observation stations in order to identify an atmospheric state at a specified time. The synoptic weather observation provides total cloud cover values from 0 to 10, but does not include forecast information, and an observation point is limited.

Korean Patent Unexamined Publication No. 10-2021-0088070 (Jul. 14, 2021) discloses Device and Method for Forecasting Renewable Energy Generation Using Ensemble Machine Learning.

### SUMMARY OF THE INVENTION

The present disclosure has been made in an effort to provide a method for predicting solar power generation by applying cloud cover prediction information and weather information based on a satellite image to a solar radiation amount prediction model.

Meanwhile, a technical object to be achieved by the present disclosure is not limited to the above-mentioned technical object, and various technical objects can be included within the scope which is apparent to those skilled in the art from contents to be described below.

An exemplary embodiment of the present disclosure provides a method for predicting a solar radiation amount by using a solar radiation amount prediction model, which is performed by a computing device. The method may include: inputting weather information into a solar radiation amount prediction model performing time series prediction; additionally inputting cloud cover prediction information into the solar radiation amount prediction model; and predicting a solar radiation amount based on the weather information and the cloud cover prediction information by using the solar radiation amount prediction model.

As an exemplary embodiment, the inputting of the weather information into the solar radiation amount prediction model may include inputting the weather information into an encoder of the solar radiation amount prediction model, and obtaining a context vector based on the weather information by using the encoder of the solar radiation amount prediction model.

As an exemplary embodiment, the inputting of the weather information into the solar radiation amount prediction model may further include inputting the obtained context vector into a decoder of the solar radiation amount prediction model.

As an exemplary embodiment, the additionally inputting of the cloud cover prediction information into the solar radiation amount prediction model may include additionally inputting the cloud cover prediction information into the decoder of the solar radiation amount prediction model.

As an exemplary embodiment, the predicting of the solar radiation amount based on the weather information and the cloud cover prediction information may include predicting the solar radiation amount based on the weather information and the cloud cover prediction information by using the decoder of the solar radiation amount prediction model.

As an exemplary embodiment, the weather information may include weather information at a previous time of a prediction time, and the cloud cover prediction information may include cloud cover prediction information for the prediction time, and the predicting of the solar radiation amount based on the weather information and the cloud cover prediction information may include predicting a solar radiation amount for the prediction time.

As an exemplary embodiment, in the additionally inputting of the cloud cover prediction information into the solar radiation amount prediction model, the weather information at the previous time of the prediction time and the cloud cover prediction information for the prediction time may be concatenated, and transferred as an input of a decoder cell corresponding to the prediction time among a plurality of decoder cells included in the decoder of the solar radiation amount prediction model.

As an exemplary embodiment, the cloud cover prediction information may be cloud cover prediction information calculated based on a satellite image predicted by using a time series prediction model.

As an exemplary embodiment, the weather information may include weather observation data, and cloud cover information calculated based on a cloud detection result.

As an exemplary embodiment, the cloud cover information may be cloud cover information calculated by quantifying a cloud cover for each class, and combining a cloud cover for each pixel for a target region based on the quantified cloud cover, in the cloud detection result in which each pixel is classified for each class.

Further, another exemplary embodiment of the present disclosure provides a computer program stored in a computer-readable storage medium. The computer program may execute the following operations for predicting a solar radiation amount by using a solar radiation amount prediction model when the computer program is executed by one or more processors, and the operations may include: an operation of inputting weather information into a solar radiation amount prediction model performing time series prediction; an operation of additionally inputting cloud cover prediction information into the solar radiation amount prediction model; and an operation of predicting a solar radiation amount based on the weather information and the cloud cover prediction information by using the solar radiation amount prediction model.

Further, yet another exemplary embodiment of the present disclosure provides a computing device. The computing device may include: a processor including at least one core; and a memory including program codes executable by the processor, and the processor may be configured to input weather information into a solar radiation amount prediction model performing time series prediction, additionally input cloud cover prediction information into the solar radiation amount prediction model, and predict a solar radiation amount based on the weather information and the cloud cover prediction information by using the solar radiation amount prediction model.

According to an exemplary embodiment of the present disclosure, there is an effect in that a solar radiation amount is predicted by applying satellite image based cloud cover prediction information to a solar radiation amount prediction model to increase the accuracy of the solar radiation amount prediction model.

Further, there is an effect in that since a solar power generation can be stably predicted even in a ramping phenomenon, the stable prediction can contribute to a stable power operation.

Meanwhile, the effects of the present disclosure are not limited to the above-mentioned effects, and various effects can be included within the scope which is apparent to those skilled in the art from contents to be described below.

### BRIEF DESCRIPTION OF THE DRAWINGS

FIG. 1 is a block diagram of a computing device performing actions according to an exemplary embodiment of the present disclosure.

FIG. 2 is a schematic view illustrating a neural network according to an exemplary embodiment of the present disclosure.

FIG. 3 is a flowchart for describing a method for predicting a solar radiation amount by using a solar radiation amount prediction model according to an exemplary embodiment of the present disclosure.

FIG. 4 is a block diagram illustrating a solar radiation amount prediction model according to an exemplary embodiment of the present disclosure.

FIG. 5 is a diagram illustrating a cloud detection result according to an exemplary embodiment of the present disclosure.

FIG. 6 is a flowchart for describing a method for calculating cloud cover information based on a cloud detection image according to an exemplary embodiment of the present disclosure.

FIG. 7 is a graph illustrating a correlation coefficient between the cloud cover calculated based on the cloud detection image and total cloud cover data according to an exemplary embodiment of the present disclosure.

FIG. 8 is a diagram specifically illustrating the solar radiation amount prediction model according to an exemplary embodiment of the present disclosure.

FIG. 9 is a block diagram illustrating a time-series prediction model according to an exemplary embodiment of the present disclosure.

FIG. 10 illustrates an example of predicting a satellite image by using an ST-LSTM based encoder-decoder model according to an exemplary embodiment of the present disclosure.

FIG. 11 is a diagram for describing a method for calculating cloud cover prediction information for a target region according to an exemplary embodiment of the present disclosure.

FIGS. 12A, 12B, 13A, and 13B are diagrams for comparing a performance difference of a solar radiation amount prediction model according to an exemplary embodiment of the present disclosure.

FIG. 14 is a simple and normal schematic view of an exemplary computing environment in which the exemplary embodiments of the present disclosure may be implemented.

### DETAILED DESCRIPTION

Various exemplary embodiments will now be described with reference to drawings. In the present specification, various descriptions are presented to provide appreciation of the present disclosure. However, it is apparent that the exemplary embodiments can be executed without the specific description.

“Component”, “module”, “system”, and the like which are terms used in the specification refer to a computer-related entity, hardware, firmware, software, and a combination of the software and the hardware, or execution of the software. For example, the component may be a processing procedure executed on a processor, the processor, an object, an execution thread, a program, and/or a computer, but is not limited thereto. For example, both an application executed in a computing device and the computing device may be the components. One or more components may reside within the processor and/or a thread of execution. One component may be localized in one computer. One component may be distributed between two or more computers. Further, the components may be executed by various computer-readable media having various data structures, which are stored therein. The components may perform communication through local and/or remote processing according to a signal (for example, data transmitted from another system through a network such as the Internet through data and/or a signal from one component that interacts with other components in a local system and a distribution system) having one or more data packets, for example.

The term “or” is intended to mean not exclusive “or” but inclusive “or”. That is, when not separately specified or not clear in terms of a context, a sentence “X uses A or B” is intended to mean one of the natural inclusive substitutions. That is, the sentence “X uses A or B” may be applied to any of the case where X uses A, the case where X uses B, or the case where X uses both A and B. Further, it should be understood that the term “and/or” used in this specification designates and includes all available combinations of one or more items among enumerated related items.

It should be appreciated that the term “comprise” and/or “comprising” means presence of corresponding features and/or components. However, it should be appreciated that the term “comprises” and/or “comprising” means that presence or addition of one or more other features, components, and/or a group thereof is not excluded. Further, when not separately specified or it is not clear in terms of the context that a singular form is indicated, it should be construed that the singular form generally means “one or more” in this specification and the claims.

The term “at least one of A or B” should be interpreted to mean “a case including only A”, “a case including only B”, and “a case in which A and B are combined”.

Those skilled in the art need to recognize that various illustrative logical blocks, configurations, modules, circuits, means, logic, and algorithm steps described in connection with the exemplary embodiments disclosed herein may be additionally implemented as electronic hardware, computer software, or combinations of both sides. To clearly illustrate the interchangeability of hardware and software, various illustrative components, blocks, configurations, means, logic, modules, circuits, and steps have been described above generally in terms of their functionalities. Whether the functionalities are implemented as the hardware or software depends on a specific application and design restrictions given to an entire system. Skilled artisans may implement the described functionalities in various ways for each particular application. However, such implementation decisions should not be interpreted as causing a departure from the scope of the present disclosure.

The description of the presented exemplary embodiments is provided so that those skilled in the art of the present disclosure use or implement the present disclosure. Various modifications to the exemplary embodiments will be apparent to those skilled in the art. Generic principles defined herein may be applied to other embodiments without departing from the scope of the present disclosure. Therefore, the present disclosure is not limited to the exemplary embodiments presented herein. The present disclosure should be analyzed within the widest range which is coherent with the principles and new features presented herein.

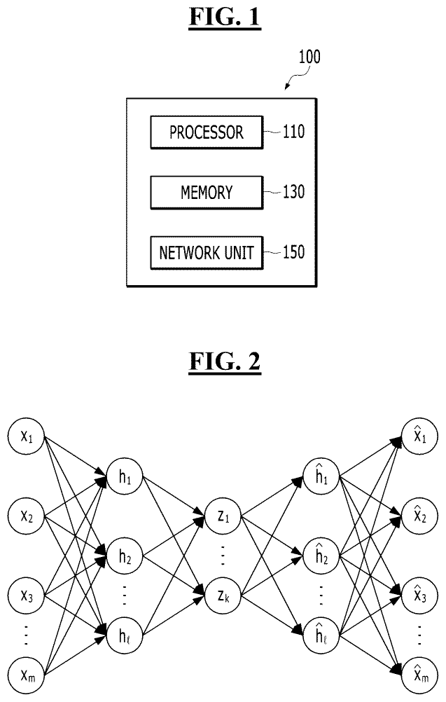

FIG. 1 is a block diagram of a computing device performing actions according to an exemplary embodiment of the present disclosure.

A configuration of the computing device 100 illustrated in FIG. 1 is only an example shown through simplification. In an exemplary embodiment of the present disclosure, the computing device 100 may include other components for performing a computing environment of the computing device 100 and only some of the disclosed components may constitute the computing device 100.

The computing device 100 may include a processor 110, a memory 130, and a network unit 150.

The processor 110 may be constituted by one or more cores and may include processors for data analysis and deep learning, which include a central processing unit (CPU), a general purpose graphics processing unit (GPGPU), a tensor processing unit (TPU), and the like of the computing device. The processor 110 may read a computer program stored in the memory 130 to perform data processing for machine learning according to an exemplary embodiment of the present disclosure. According to an exemplary embodiment of the present disclosure, the processor 110 may perform a calculation for learning the neural network. The processor 110 may perform calculations for learning the neural network, which include processing of input data for learning in deep learning (DL), extracting a feature in the input data, calculating an error, updating a weight of the neural network using backpropagation, and the like. At least one of the CPU, GPGPU, and TPU of the processor 110 may process learning of a network function. For example, both the CPU and the GPGPU may process the learning of the network function and data classification using the network function. Further, in an exemplary embodiment of the present disclosure, processors of a plurality of computing devices may be used together to process the learning of the network function and the data classification using the network function. Further, the computer program executed in the computing device according to an exemplary embodiment of the present disclosure may be a CPU, GPGPU, or TPU executable program.

The computing device 100 according to an exemplary embodiment of the present disclosure may mean a solar power generation prediction system. The computing device 100 may predict a solar radiation amount by using a solar radiation amount prediction model, and predict a solar power generation by using the predicted solar radiation amount.

As an example, the computing device 100 may obtain a forecasted weather element and the predicted solar radiation amount, and predict the solar power generation based on the forecasted weather element and the predicted solar radiation amount by using a deep neural network (DNN).

The solar radiation amount prediction model may be a recurrent neural network (RNN) based encoder-decoder model for time series forecasting. The time series forecasting means a technology that observes time series data sequentially recorded according to the flow of time, and predicts a future by analyzing the observed time series data. The solar radiation amount prediction model may also be a single-step time series prediction model that predicts only one time step at one time, and may be a multi-step time series prediction model that predicts multiple time steps at one time.

The RNN is a most basic sequence model of deep learning. The RNN has an iterative structure of calculating a new hidden state by combining a hidden state of a previous time step and an input of a current time step. The hidden state of the RNN indicates hidden information in each time step. However, the RNN has a long-term dependency problem.

As a model acquired by improving the RNN, there are a long short term memory (LSTM) and a gated recurrent unit (GRU).

The LSTM includes a cell state serving as a memory. The cell state of the LSTM is updated by using an input gate, a deletion gate, and an output gate. The input gate determines how much information is to be added to the cell state by considering the input of the current time step and the hidden state of the previous time step. The deletion gate determines which information is to be deleted in a previous cell state by considering the cell state of the previous time step and the input of the current time step. The output gate determines how many cell states are to be exposed to the hidden state of the current time step by considering the input of the current time step and the hidden state of the previous time step. Through this, the LSTM solves the long term dependency problem of the RNN.

The GRU has a similar structure to the LSTM, but has a simpler structure than the LSTM. The GRU includes an update gate in which the input gate and the deletion gate of the LSTM are combined, and a reset gate. The GRU processes only the hidden state by using the update gate and the reset gate. Accordingly, the GRU is a model that is lighter than the LSTM.

Each of the encoder and the decoder of the solar radiation amount prediction model of the present disclosure may include at least one of the RNN, the LSTM, and the GRU.

The computing device 100 may input weather information into the solar radiation amount prediction model that performs the time series prediction. In some exemplary embodiments, the weather information may include data having a correlation with the solar power generation among the weather observation data. For example, the weather information may include temperature, sunshine, and solar radiation.

In some exemplary embodiments, the weather information may further include cloud cover information calculated based on the cloud detection result among satellite products. The cloud detection result or cloud detection image is an image in which respective pixels are classified into cloud, probably cloud, and clear which are three classes. The cloud detection result is a satellite product which the National Meteorological Satellite Center produces by using 16 channels including a visible channel, an infrared channel, etc., and auxiliary data, and becomes data that determine whether the cloud is present. The computing device 100 may quantify the cloud cover for each class in the cloud detection result, and determine pixel regions corresponding to the whole sky region, through a similarity analysis to the total cloud cover data of an automated surface observation system (ASOS). The computing device 100 may calculate cloud cover information of a target region by considering two parameters determined through the similarity analysis, i.e., i) the numerical value of cloud cover granted to an intermediate class of the cloud detection result, and ii) the total number of pixels of the pixels regions corresponding to the whole sky region.

The computing device 100 may additionally input cloud cover prediction information to the solar radiation amount prediction model. The cloud cover prediction information may be satellite image based cloud cover prediction information. The computing device 100 may input a plurality of satellite products into the time series prediction model. The computing device 100 may predict a satellite image based on the plurality of satellite products by using the time series prediction model. The computing device 100 may calculate cloud cover prediction information for the target region from the predicted satellite image. As an example, the predicted satellite image may be the cloud detection image which is a prediction result for cloud detection among the plurality of satellite products. The cloud cover prediction information may be information calculated based on the predicted cloud detection image.

The computing device 100 may predict the solar radiation amount based on the weather information and the cloud cover prediction information by using the solar radiation amount prediction model.

The method for predicting the solar power generation of the present disclosure uses satellite image based cloud cover prediction information for power generation prediction to increase the accuracy of the solar radiation amount prediction, and contribute to a stable power operation of the solar power generation.

According to an exemplary embodiment of the present disclosure, the memory 130 may store any type of information generated or determined by the processor 110 and any type of information received by the network unit 150.

According to an exemplary embodiment of the present disclosure, the memory 130 may include at least one type of storage medium of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The computing device 100 may operate in connection with a web storage performing a storing function of the memory 130 on the Internet. The description of the memory is just an example and the present disclosure is not limited thereto.

The network unit 150 according to several embodiments of the present disclosure may use various wired communication systems, such as a Public Switched Telephone Network (PSTN), an x Digital Subscriber Line (xDSL), a Rate Adaptive DSL (RADSL), a Multi Rate DSL (MDSL), a Very High Speed DSL (VDSL), a Universal Asymmetric DSL (UADSL), a High Bit Rate DSL (HDSL), and a local area network (LAN).

The network unit 150 presented in the present specification may use various wireless communication systems, such as Code Division Multi Access (CDMA), Time Division Multi Access (TDMA), Frequency Division Multi Access (FDMA), Orthogonal Frequency Division Multi Access (OFDMA), Single Carrier-FDMA (SC-FDMA), and other systems.

In the present disclosure, the network unit 150 may be configured regardless of a communication aspect, such as wired communication and wireless communication, and may be configured by various communication networks, such as a Personal Area Network (PAN) and a Wide Area Network (WAN). Further, the network may be a publicly known World Wide Web (WWW), and may also use a wireless transmission technology used in short range communication, such as Infrared Data Association (IrDA) or Bluetooth. The techniques described herein may be used in other networks in addition to those mentioned above.

FIG. 2 is a schematic diagram illustrating a network function according to an exemplary embodiment of the present disclosure.

Throughout the present specification, a computation model, the neural network, a network function, and the neural network may be used as the same meaning. The neural network may be generally constituted by an aggregate of calculation units which are mutually connected to each other, which may be called nodes. The nodes may also be called neurons. The neural network is configured to include one or more nodes. The nodes (alternatively, neurons) constituting the neural networks may be connected to each other by one or more links.

In the neural network, one or more nodes connected through the link may relatively form the relationship between an input node and an output node. Concepts of the input node and the output node are relative and a predetermined node which has the output node relationship with respect to one node may have the input node relationship in the relationship with another node and vice versa. As described above, the relationship of the input node to the output node may be generated based on the link. One or more output nodes may be connected to one input node through the link and vice versa.

In the relationship of the input node and the output node connected through one link, a value of data of the output node may be determined based on data input in the input node. Here, a link connecting the input node and the output node to each other may have a weight. The weight may be variable and the weight is variable by a user or an algorithm in order for the neural network to perform a desired function. For example, when one or more input nodes are mutually connected to one output node by the respective links, the output node may determine an output node value based on values input in the input nodes connected with the output node and the weights set in the links corresponding to the respective input nodes.

As described above, in the neural network, one or more nodes are connected to each other through one or more links to form a relationship of the input node and output node in the neural network. A characteristic of the neural network may be determined according to the number of nodes, the number of links, correlations between the nodes and the links, and values of the weights granted to the respective links in the neural network. For example, when the same number of nodes and links exist and there are two neural networks in which the weight values of the links are different from each other, it may be recognized that two neural networks are different from each other.

The neural network may be constituted by a set of one or more nodes. A subset of the nodes constituting the neural network may constitute a layer. Some of the nodes constituting the neural network may constitute one layer based on the distances from the initial input node. For example, a set of nodes of which distance from the initial input node is n may constitute n layers. The distance from the initial input node may be defined by the minimum number of links which should be passed through for reaching the corresponding node from the initial input node. However, a definition of the layer is predetermined for description and the order of the layer in the neural network may be defined by a method different from the aforementioned method. For example, the layers of the nodes may be defined by the distance from a final output node.

The initial input node may mean one or more nodes in which data is directly input without passing through the links in the relationships with other nodes among the nodes in the neural network. Alternatively, in the neural network, in the relationship between the nodes based on the link, the initial input node may mean nodes which do not have other input nodes connected through the links. Similarly thereto, the final output node may mean one or more nodes which do not have the output node in the relationship with other nodes among the nodes in the neural network. Further, a hidden node may mean nodes constituting the neural network other than the initial input node and the final output node.

In the neural network according to an exemplary embodiment of the present disclosure, the number of nodes of the input layer may be the same as the number of nodes of the output layer, and the neural network may be a neural network of a type in which the number of nodes decreases and then, increases again from the input layer to the hidden layer. Further, in the neural network according to another exemplary embodiment of the present disclosure, the number of nodes of the input layer may be smaller than the number of nodes of the output layer, and the neural network may be a neural network of a type in which the number of nodes decreases from the input layer to the hidden layer. Further, in the neural network according to yet another exemplary embodiment of the present disclosure, the number of nodes of the input layer may be larger than the number of nodes of the output layer, and the neural network may be a neural network of a type in which the number of nodes increases from the input layer to the hidden layer. The neural network according to still yet another exemplary embodiment of the present disclosure may be a neural network of a type in which the neural networks are combined.

A deep neural network (DNN) may refer to a neural network that includes a plurality of hidden layers in addition to the input and output layers. When the deep neural network is used, the latent structures of data may be determined. That is, latent structures of photos, text, video, voice, and music (e.g., what objects are in the photo, what the content and feelings of the text are, what the content and feelings of the voice are) may be determined. The deep neural network may include a convolutional neural network (CNN), a recurrent neural network (RNN), an auto encoder, generative adversarial networks (GAN), a restricted Boltzmann machine (RBM), a deep belief network (DBN), a Q network, a U network, a Siam network, a Generative Adversarial Network (GAN), and the like. The description of the deep neural network described above is just an example and the present disclosure is not limited thereto.

In an exemplary embodiment of the present disclosure, the network function may include the auto encoder. The auto encoder may be a kind of artificial neural network for outputting output data similar to input data. The auto encoder may include at least one hidden layer and odd hidden layers may be disposed between the input and output layers. The number of nodes in each layer may be reduced from the number of nodes in the input layer to an intermediate layer called a bottleneck layer (encoding), and then expanded symmetrical to reduction to the output layer (symmetrical to the input layer) in the bottleneck layer. The auto encoder may perform non-linear dimensional reduction. The number of input and output layers may correspond to a dimension after preprocessing the input data. The auto encoder structure may have a structure in which the number of nodes in the hidden layer included in the encoder decreases as a distance from the input layer increases. When the number of nodes in the bottleneck layer (a layer having a smallest number of nodes positioned between an encoder and a decoder) is too small, a sufficient amount of information may not be delivered, and as a result, the number of nodes in the bottleneck layer may be maintained to be a specific number or more (e.g., half of the input layers or more).

The neural network may be learned in at least one scheme of supervised learning, unsupervised learning, semi i supervised learning, or reinforcement learning. The learning of the neural network may be a process in which the neural network applies knowledge for performing a specific operation to the neural network.

The neural network may be learned in a direction to minimize errors of an output. The learning of the neural network is a process of repeatedly inputting training data into the neural network and calculating the output of the neural network for the training data and the error of a target and back-propagating the errors of the neural network from the output layer of the neural network toward the input layer in a direction to reduce the errors to update the weight of each node of the neural network. In the case of the supervised learning, the training data labeled with a correct answer is used for each training data (i.e., the labeled training data) and in the case of the unsupervised learning, the correct answer may not be labeled in each training data. That is, for example, the training data in the case of the supervised learning related to the data classification may be data in which category is labeled in each training data. The labeled training data is input to the neural network, and the error may be calculated by comparing the output (category) of the neural network with the label of the training data. As another example, in the case of the unsupervised learning related to the data classification, the training data as the input is compared with the output of the neural network to calculate the error. The calculated error is back-propagated in a reverse direction (i.e., a direction from the output layer toward the input layer) in the neural network and connection weights of respective nodes of each layer of the neural network may be updated according to the back propagation. A variation amount of the updated connection weight of each node may be determined according to a learning rate. Calculation of the neural network for the input data and the back-propagation of the error may constitute a learning cycle (epoch). The learning rate may be applied differently according to the number of repetition times of the learning cycle of the neural network. For example, in an initial stage of the learning of the neural network, the neural network ensures a certain level of performance quickly by using a high learning rate, thereby increasing efficiency and uses a low learning rate in a latter stage of the learning, thereby increasing accuracy.

In learning of the neural network, the training data may be generally a subset of actual data (i.e., data to be processed using the learned neural network), and as a result, there may be a learning cycle in which errors for the training data decrease, but the errors for the actual data increase. Overfitting is a phenomenon in which the errors for the actual data increase due to excessive learning of the training data. For example, a phenomenon in which the neural network that learns a cat by showing a yellow cat sees a cat other than the yellow cat and does not recognize the corresponding cat as the cat may be a kind of overfitting. The overfitting may act as a cause which increases the error of the machine learning algorithm. Various optimization methods may be used in order to prevent the overfitting. In order to prevent the overfitting, a method such as increasing the training data, regularization, dropout of omitting a part of the node of the network in the process of learning, utilization of a batch normalization layer, etc., may be applied.

In the meantime, according to an embodiment of the present disclosure, a computer readable medium storing a data structure is disclosed.

The data structure may refer to organization, management, and storage of data that enable efficient access and modification of data. The data structure may refer to organization of data for solving a specific problem (for example, data search, data storage, and data modification in the shortest time). The data structure may also be defined with a physical or logical relationship between the data elements designed to support a specific data processing function. A logical relationship between data elements may include a connection relationship between user defined data elements. A physical relationship between data elements may include an actual relationship between the data elements physically stored in a computer readable storage medium (for example, a permanent storage device). In particular, the data structure may include a set of data, a relationship between data, and a function or a command applicable to data. Through the effectively designed data structure, the computing device may perform a calculation while minimally using resources of the computing device. In particular, the computing device may improve efficiency of calculation, reading, insertion, deletion, comparison, exchange, and search through the effectively designed data structure.

The data structure may be divided into a linear data structure and a non-linear data structure according to the form of the data structure. The linear data structure may be the structure in which only one data is connected after one data. The linear data structure may include a list, a stack, a queue, and a deque. The list may mean a series of dataset in which order exists internally. The list may include a linked list. The linked list may have a data structure in which data is connected in a method in which each data has a pointer and is linked in a single line. In the linked list, the pointer may include information about the connection with the next or previous data. The linked list may be expressed as a single linked list, a double linked list, and a circular linked list according to the form. The stack may have a data listing structure with limited access to data. The stack may have a linear data structure that may process (for example, insert or delete) data only at one end of the data structure. The data stored in the stack may have a data structure (Last In First Out, LIFO) in which the later the data enters, the sooner the data comes out. The queue is a data listing structure with limited access to data, and may have a data structure (First In First Out, FIFO) in which the later the data is stored, the later the data comes out, unlike the stack. The deque may have a data structure that may process data at both ends of the data structure.

The non-linear data structure may be the structure in which the plurality of data is connected after one data. The non-linear data structure may include a graph data structure. The graph data structure may be defined with a vertex and an edge, and the edge may include a line connecting two different vertexes. The graph data structure may include a tree data structure. The tree data structure may be the data structure in which a path connecting two different vertexes among the plurality of vertexes included in the tree is one. That is, the tree data structure may be the data structure in which a loop is not formed in the graph data structure.

The data structure may include a neural network. Further, the data structure including the neural network may be stored in a computer readable medium. The data structure including the neural network may also include preprocessed data for processing by the neural network, data input to the neural network, a weight of the neural network, a hyper-parameter of the neural network, data obtained from the neural network, an active function associated with each node or layer of the neural network, and a loss function for training of the neural network. The data structure including the neural network may include predetermined configuration elements among the disclosed configurations. That is, the data structure including the neural network may include the entirety or a predetermined combination of pre-processed data for processing by neural network, data input to the neural network, a weight of the neural network, a hyper parameter of the neural network, data obtained from the neural network, an active function associated with each node or layer of the neural network, and a loss function for training the neural network. In addition to the foregoing configurations, the data structure including the neural network may include predetermined other information determining a characteristic of the neural network. Further, the data structure may include all type of data used or generated in a computation process of the neural network, and is not limited to the foregoing matter. The computer readable medium may include a computer readable recording medium and/or a computer readable transmission medium. The neural network may be formed of a set of interconnected calculation units which are generally referred to as “nodes”. The “nodes” may also be called “neurons.” The neural network consists of one or more nodes.

The data structure may include data input to the neural network. The data structure including the data input to the neural network may be stored in the computer readable medium. The data input to the neural network may include training data input in the training process of the neural network and/or input data input to the training completed neural network. The data input to the neural network may include data that has undergone pre-processing and/or data to be pre-processed. The pre-processing may include a data processing process for inputting data to the neural network. Accordingly, the data structure may include data to be pre-processed and data generated by the pre-processing. The foregoing data structure is merely an example, and the present disclosure is not limited thereto.

The data structure may include a weight of the neural network (in the present specification, weights and parameters may be used with the same meaning), Further, the data structure including the weight of the neural network may be stored in the computer readable medium. The neural network may include a plurality of weights. The weight is variable, and in order for the neural network to perform a desired function, the weight may be varied by a user or an algorithm. For example, when one or more input nodes are connected to one output node by links, respectively, the output node may determine a data value output from the output node based on values input to the input nodes connected to the output node and the weight set in the link corresponding to each of the input nodes. The foregoing data structure is merely an example, and the present disclosure is not limited thereto.

For a non-limited example, the weight may include a weight varied in the neural network training process and/or the weight when the training of the neural network is completed. The weight varied in the neural network training process may include a weight at a time at which a training cycle starts and/or a weight varied during a training cycle. The weight when the training of the neural network is completed may include a weight of the neural network completing the training cycle. Accordingly, the data structure including the weight of the neural network may include the data structure including the weight varied in the neural network training process and/or the weight when the training of the neural network is completed. Accordingly, it is assumed that the weight and/or a combination of the respective weights are included in the data structure including the weight of the neural network. The foregoing data structure is merely an example, and the present disclosure is not limited thereto.

The data structure including the weight of the neural network may be stored in the computer readable storage medium (for example, a memory and a hard disk) after undergoing a serialization process. The serialization may be the process of storing the data structure in the same or different computing devices and converting the data structure into a form that may be reconstructed and used later. The computing device may serialize the data structure and transceive the data through a network. The serialized data structure including the weight of the neural network may be reconstructed in the same or different computing devices through deserialization. The data structure including the weight of the neural network is not limited to the serialization. Further, the data structure including the weight of the neural network may include a data structure (for example, in the non-linear data structure, B-Tree, Trie, m-way search tree, AVL tree, and Red-Black Tree) for improving efficiency of the calculation while minimally using the resources of the computing device. The foregoing matter is merely an example, and the present disclosure is not limited thereto.

The data structure may include a hyper-parameter of the neural network. The data structure including the hyper-parameter of the neural network may be stored in the computer readable medium. The hyper-parameter may be a variable varied by a user. The hyper-parameter may include, for example, a learning rate, a cost function, the number of times of repetition of the training cycle, weight initialization (for example, setting of a range of a weight value to be weight-initialized), and the number of hidden units (for example, the number of hidden layers and the number of nodes of the hidden layer). The foregoing data structure is merely an example, and the present disclosure is not limited thereto.

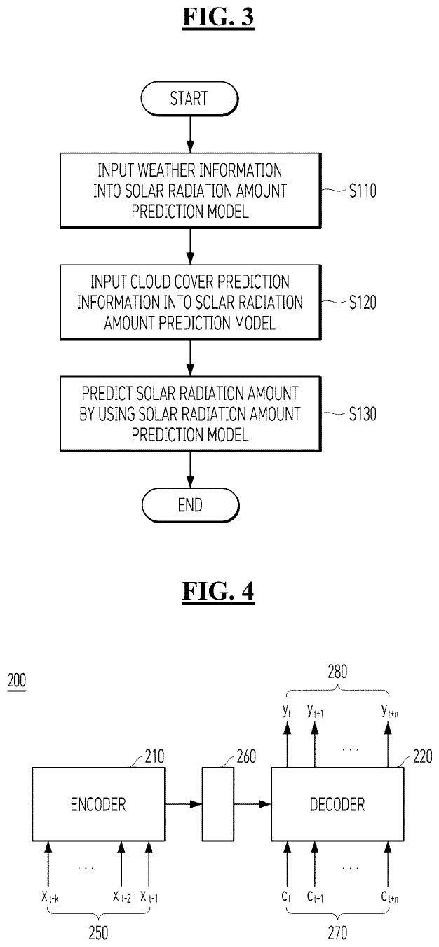

FIG. 3 is a flowchart for describing a method for predicting a solar radiation amount by using a solar radiation amount prediction model according to an exemplary embodiment of the present disclosure and FIG. 4 is a block diagram illustrating a solar radiation amount prediction model according to an exemplary embodiment of the present disclosure.

Referring to FIGS. 3 and 4 jointly, the computing device may input weather information xₜ₋ₖ, . . . , xₜ₋₂, xₜ₋₁; 250 which is time series data into the solar radiation amount prediction model 200 performing time series prediction (S110). The weather information 250 may include data having a correlation with the solar power generation among the weather observation data. For example, the weather observation information may include temperature, sunshine, and solar radiation. In some exemplary embodiments, the weather information 250 may further include cloud cover information calculated based on the cloud detection result among satellite products.

The computing device may additionally input cloud cover prediction information cₜ, cₜ₊₁, . . . , cₜ₊ₙ; 270 into the solar radiation amount prediction model 200 (S120). The cloud cover prediction information 270 may be information calculated based on the satellite image predicted by using the time series prediction model. As an example, an input of the time series prediction model may be a plurality of satellite products, and the predicted satellite image may be a cloud detection image which is a prediction result for cloud detection among the plurality of satellite products. The cloud cover prediction information 270 may be information calculated based on the predicted cloud detection image.

The computing device may predict a solar radiation amount yₜ, yₜ₊₁, . . . , yₜ₊ₙ; 280 based on the weather information 250 and the cloud cover prediction information 270 by using the solar radiation amount prediction model 200. In FIG. 4, the solar radiation amount prediction model 200 is illustrated and described as a multi-step time series prediction model that predicts multiple time steps at one time, but the solar radiation amount prediction model 200 of the present disclosure may also be a single step time series prediction model that predicts only one time step at one time.

The solar radiation amount prediction model 200 may include an encoder 210 and a decoder 220. Each of the encoder 210 and the decoder 220 may include at least one of the RNN, the LSTM, and the GRU.

The computing device may input the weather information 250 into the encoder 210. The computing device may obtain a context vector 260 based on the weather information 250 by using the encoder 210.

The computing device may input the context vector 260 and the cloud cover prediction information 270 into the decoder 220. The computing device may predict the solar radiation amount 280 based on the context vector 260 and the cloud cover prediction information 270 by using the decoder 220.

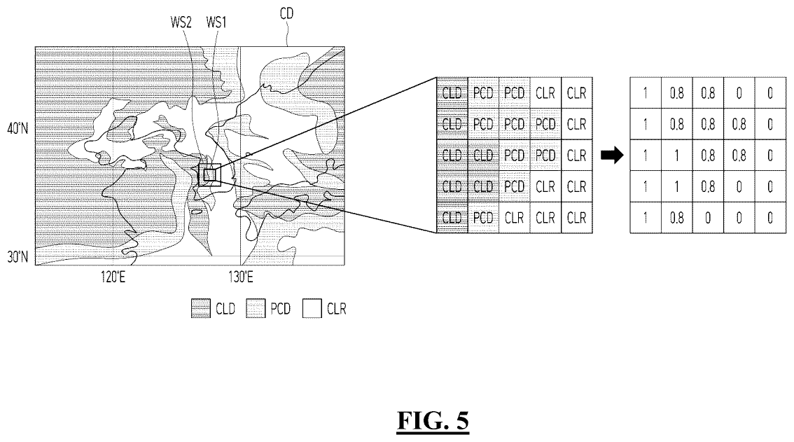

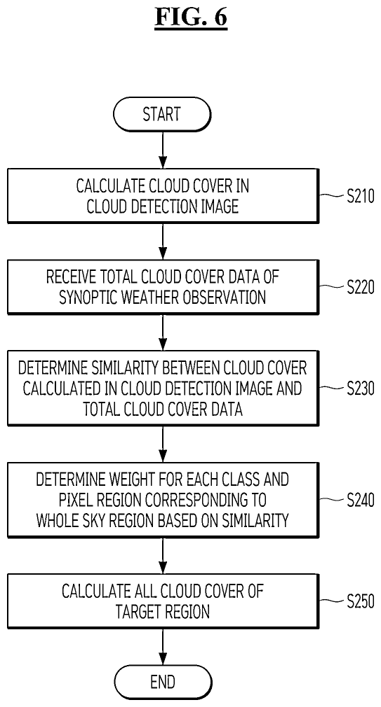

The weather information 250 input into the encoder 210 of the solar radiation amount prediction model 200 may include cloud cover information calculated based on the cloud detection result among the satellite products. A specific method in which the computing device quantifies the cloud cover and calculates the cloud cover information will be described with reference to FIGS. 5 and 6.

FIG. 5 is a diagram illustrating a cloud detection result according to an exemplary embodiment of the present disclosure.

Referring to FIG. 5, in a cloud detection result CD among satellite products, respective pixels are classified into cloud (CLD), probability cloud (PCD), and clear (CLR) which are three classes. The computing device applies the ‘cloud (CLD)’ class to ‘1’, and applies the ‘clear (CLD)’ class to ‘0’ to distinguish a definite cloud and a definite clear, and determine a confidential level of ‘the probability cloud (PCD)’ class which is an intermediate class in a formula type. As an example, the computing device may quantify the cloud cover to ‘0.8’ in the probably cloud (PCD) class through similarity analysis.

When a cloud cover of a specific region is calculated, it should be known how many pixels a sky covering the target region corresponds to in the cloud detection result. The computing device may define a plurality of pixel regions WS1 and WS2 based on the target region. The computing device may determine a pixel region (e.g., WS1) corresponding to whole sky region among the plurality of pixel regions WS1 and WS2 through similarity analysis.

The computing device may calculate cloud cover information of a target region by considering two parameters, i.e., i) a numerical value of cloud cover granted to an intermediate class of the cloud detection result, and ii) the total number of pixels of the pixels regions corresponding to the whole sky region.

FIG. 6 is a flowchart for describing a method for calculating cloud cover information based on a cloud detection image according to an exemplary embodiment of the present disclosure.

Referring to FIG. 6, the computing device may calculate a cloud cover of a target region based on a cloud detection image (S210). When a weight of the ‘cloud’ class is ‘1’ and a weight of the ‘clear’ class is ‘0’, the cloud cover may be represented as in [Equation 1].

$$Cloud cover = \frac{\begin{matrix}( number of pixels of probably cloud class ) \times w + \\ ( number of pixels of cloud class )\end{matrix}}{total number of pixels} \qquad [ Equation 1 ]$$

Where w means the weight of the ‘probably cloud’ class, and the total number of pixels means the total number of pixels of the pixel region corresponding to the whole sky region. The pixel region means an area of calculating the cloud cover.

The computing device may calculate the cloud cover while increasing the weight w of the ‘probably cloud’ class from 0 to 1. The computing device may find an optimal weight w through the similarity analysis.

When the cloud cover of the specific region is quantified, the total number of pixels of the pixel region corresponding to the whole sky region in the cloud detection image should be known. The whole sky region may mean a sky covering the target region. The area of the whole sky region may be determined as one of a plurality of areas defined based on the target region. As an example, when a cloud cover of Shintanjin is quantified, the area of the whole sky region may also be an area corresponding to the Shintanjin, or also an area of the entire Daejeon. Accordingly, the computing device may define candidate areas of the whole sky region based on the target region in the cloud detection image. The computing device may define a plurality of pixel regions corresponding to the candidate areas of the whole sky region. The computing device may determine a pixel region corresponding to the whole sky region among the plurality of pixel regions through similarity analysis.

The computing device may calculate each cloud cover according to the weight w of the ‘probably cloud’ class and the plurality of pixel regions corresponding to the candidate areas of the whole sky region.

The computing device may receive total cloud cover data of an automated surface observation system (ASOS) of the Meteorological Agency (S220). The computing device may determine a similarity between the cloud cover calculated in the cloud detection image and the total cloud cover data (S230). The ASOS data means data observed with naked eyes in all ground observation stations at the same time. Accordingly, the ASOS data has a limit in terms of an observation point and an observation time. Currently, in Korea, 103 ground observation stations provide the all cloud cover data at an interval of 1 hour. However, a geostationary orbital satellite takes the entire earth image at an interval of 10 minutes. Accordingly, when the cloud cover is calculated by using the satellite image, the limit in the observation point may be overcome, and a cloud cover having a temporal/spatial resolution may be calculated.

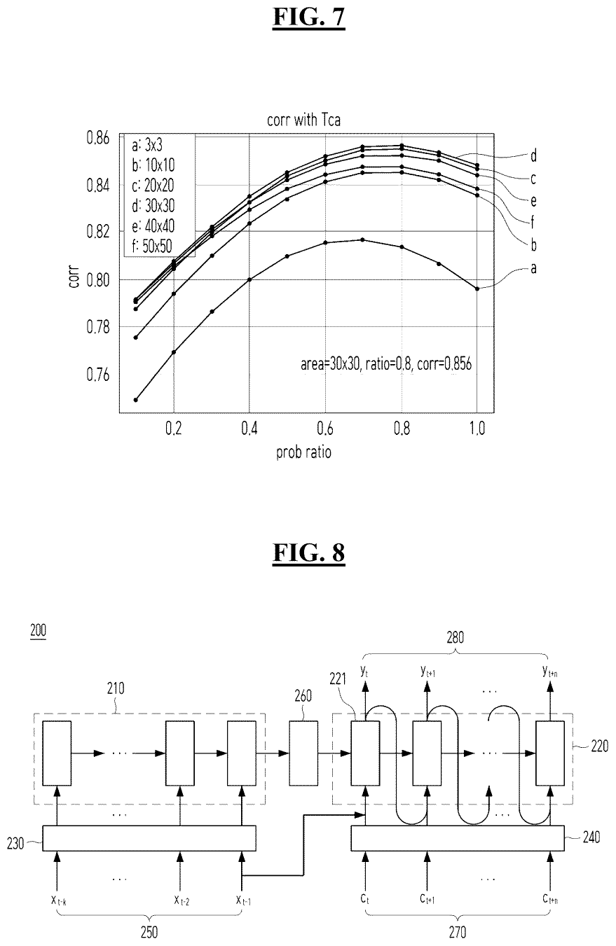

FIG. 7 is a graph illustrating a correlation coefficient between the cloud cover calculated based on the cloud detection image and total cloud cover data according to an exemplary embodiment of the present disclosure.

Referring to FIG. 7, an x axis indicates the weight of the ‘probably cloud’ class, a y axis indicates a correlation coefficient between the cloud cover calculated based on the cloud detection image and the total cloud cover data, and lines a to f indicate pixel regions corresponding to the candidate areas of the whole sky region.

The computing device may calculate each cloud cover according to the weight w of the ‘probably cloud’ class and the plurality of pixel regions corresponding to the candidate areas of the whole sky region.

As an example, the plurality of pixel regions corresponding to the candidate areas of the whole sky region may be 3×3, 10×10, 20×20, 30×30, 40×40, and 50×50. The computing device may calculate each cloud cover while increasing the weight w of the ‘probably cloud’ class from 0 to 1 for each of the plurality of pixel regions. The computing device may calculate a Pearson correlation coefficient between the calculated cloud cover and the whole sky cloud cover data.

The Pearson correlation coefficient is a statistical index that measures a strength and a direction of a linear relationship between two variables. The Pearson correlation coefficient as a value indicating how both variables are related to each other has a range from −1 to 1. The closer the value of the Pearson correlation coefficient is to 1, the stronger a positive linear relationship is, and the closer the value of the Pearson correlation coefficient is to −1, the stronger a negative linear relationship is. The value of the Pearson correlation coefficient being closer to 0 indicates that there is almost no linear relationship between both variables, or there is a weak linear relationship between both variables.

In the example illustrated in FIG. 7, when the weight of the ‘probably cloud’ class is ‘0.8’, in a 30×30 pixel region d, the cloud cover calculated based on the cloud detection image and the whole sky cloud cover data are most similar.

Referring back to FIG. 6, the computing device may determine the weight for each class and the pixel region corresponding to the whole sky region based on the similarity (S240). In the example illustrated in FIG. 7, the computing device may determine the weight of the ‘probably cloud’ as 0.8′ class through the similarity analysis, and determine the pixel region corresponding to the all-sky region as 30×30.

The computing device may determine the cloud cover for each pixel of the target region based on the quantified cloud cover, and integrates the cloud cover for each pixel to calculate a total cloud cover of the target region. The computing device may calculate the total cloud cover of the target region by using [Equation 1] above.

FIG. 8 is a diagram specifically illustrating the solar radiation amount prediction model according to an exemplary embodiment of the present disclosure.

Referring to FIG. 8, the solar radiation amount prediction model 200 may include an encoder 210, a decoder 220, a first embedding layer 230, and a second embedding layer 240. The encoder 210 may include a plurality of encoder cells, and the decoder 200 may include a plurality of decoder cells. Each of the plurality of encoder cells and the plurality of decoder cells may be one of the RNN, the LSTM, and the GRU.

The computing device may input the weather information 250 which is the time series data into the solar radiation amount prediction model 200 that performs time series prediction. The weather information 250 may include weather observation data including temperature, sunshine, solar radiation, etc., and cloud cover information calculated based on a cloud detection result. The first embedding layer 230 may convert the weather information 250 into a first embedding vector which is a low-dimensional dense vector. The encoder 210 may obtain the converted first embedding vector, and obtain the context vector 260 based on the embedding vector.

The computing device may additionally input the cloud cover prediction information 270 into the solar radiation amount prediction model 200. The second embedding layer 240 may convert the cloud cover prediction information 270 into a second embedding vector which is a low-dimensional dense vector. The decoder 220 may obtain the converted second embedding vector and the context vector 260. The decoder 220 may predict the solar radiation amount 280 based on the second embedding vector and the context vector 260.

In some exemplary embodiments, the weather information 250 may include weather information at a previous time t−k to t−1 of a prediction time t to t+n. The cloud cover prediction information 270 may include cloud cover prediction information for the prediction time t to t+n. The solar radiation amount prediction model 200 may predict the solar radiation amount 280 for the prediction time t to t+n based on the weather information 250 and the cloud cover prediction information 270.

The weather information at the previous time t−k to t−1 of the prediction time t to t+n, and the cloud cover prediction information for the prediction time t to t+n may be concatenated to each other. As an example, weather information xₜ₋₁ at one time t−1 among the previous time t−k to t−1 of the prediction time t to t+n, and cloud cover prediction information cₜ for a time t among the prediction time t to t+n may be concatenated to each other. The weather information xₜ₋₁ at the time t−1 may include the solar radiation amount. Specifically, a second embedding vector of the cloud cover prediction information cₜ for the time t and the weather information xₜ₋₁ at the time t−1 may be concatenated to each other. The concatenated information may be transferred as an input of a decoder cell 221 corresponding to the time t among a plurality of decoder cells included in the decoder 220.

The cloud cover prediction information 270 may be information calculated based on the satellite image predicted by using the time series prediction model.

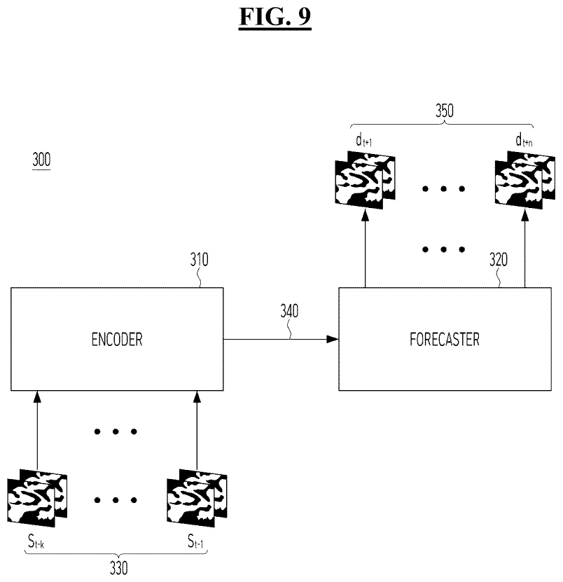

Hereinafter, a method for calculating the satellite image based cloud cover prediction information will be described with reference to FIGS. 9 to 11.

FIG. 9 is a block diagram illustrating a time-series prediction model according to an exemplary embodiment of the present disclosure.

A video prediction that predicts future frames by using previous frames may be performed by using deep learning models RNN, CNN, Vision Transformer (ViT), etc. As an example, the time series prediction model may be a multiple RNN (stacked RNN, RNN-RNN-RNN) structure in which RNN layers are stacked in multiple. In some exemplary embodiments, the time series prediction model may be a CNN-RNN-CNN structure in which the video frames are projected to a latent space, and future latent states are predicted by using the RNN. In some exemplary embodiments, the time series prediction model may be a CNN-ViT-CNN structure that models latent video dynamics by introducing the ViT.

LSTM, GRU, and spatiotemporal LSTM (ST-LSTM) which are modified models of the RNN may be applied to the models.

The time series prediction model is not limited to the above-described structure, and various structures such as an LSTM-GAN structure that predicts a future latent vector by using the LSTM, and generates an image based on the latent vector by using a generative model such as generative adversarial networks (GAN), and various methods may be adopted.

Referring to FIG. 9, the time series prediction model 300 may include an encoder 310 and a forecaster 320.

The computing device may input a plurality of satellite products Sₜ₋ₖ, . . . , Sₜ₋₁; 330 which are related to the cloud and which are time series data into the encoder 310. The plurality of satellite products 330 may include at least one of cloud detection, infrared channel data, visible channel data, vapor channel data, and short-wave infrared channel data. The plurality of satellite products 330 may be time series data before the prediction time t+1, . . . , t+n.

The computing device may obtain an internal representation 340 based on the plurality of satellite products 330 by using the encoder 310. The internal representation may mean a representation inherent in data itself or the totality of information contained in data. As an example, the internal representation may a memory state, a latent vector, a context vector, etc.

The computing device may input the internal representation 340 into the decoder 320. The computing device may predict satellite images dₜ₊₁, . . . , dₜ₊ₙ; 350 based on the internal representation 340 by using the decoder 320.

In some exemplary embodiments, the computing device may further input a prediction satellite image before the prediction time into the decoder 320. The computing device may predict the satellite images dₜ₊₁, . . . , dₜ₊ₙ; 350 based on the internal representation 340 and the prediction satellite image st before the prediction time by using the decoder 320.

The time series prediction model 300 may predict the satellite image 350 for the prediction time t+1, . . . , t+n. The time series prediction model 300 may be a single-step time series prediction model that predicts only one time step at one time, and may be a multi-step time series prediction model that predicts multiple time steps at one time.

The predicted satellite image 350 may be a prediction result for cloud detection among the plurality of satellite products 330. The computing device 350 may calculate cloud cover prediction information for the target region from the predicted satellite image 350.

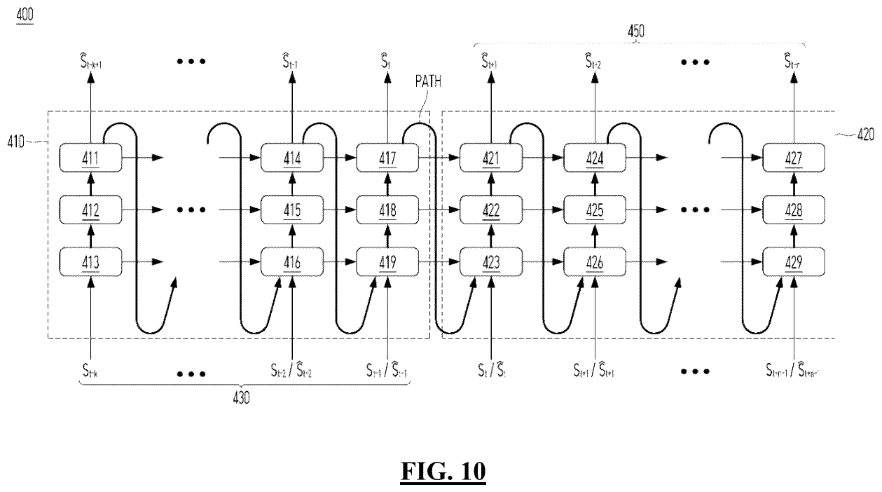

FIG. 10 illustrates an example of predicting a satellite image by using an ST-LSTM based encoder-decoder model according to an exemplary embodiment of the present disclosure.

Referring to FIG. 10, the time series prediction model 400 may include an encoder 410 and a forecaster 420. The encoder 410 may include a plurality of encoder cells 411 to 419, and the forecaster 420 may include a plurality of decoder cells 421 to 429. Each of the plurality of encoder cells 411 to 419, and the plurality of decoder cells 421 to 429 may be the ST-LSTM.

The ST-LSTM is a model that applies an improved structure to the LSTM considering spatiotemporal information. The ST-LSTM is a model that adds a spatiotemporal memory cell to a cell-state which is responsible for long-term memory and a hidden-state which is responsible for short-term memory in the LSTM to train spatiotemporal data distributions having different aspects, respectively.

Referring to a thick line of FIG. 10, a spatiotemporal memory flow may represent state transition paths (PATH) of the spatiotemporal memory. The spatiotemporal memory flow may have a flow that the memory states is transferred to different levels of layers at different points in time to pass through all layers in the network.

In a actual inference step, the encoder 410 may operate based on a true frame Sₜ₋ₖ, . . . , Sₜ₋₂, Sₜ₋₁; 430 at a corresponding time, and the forecaster 420 may perform prediction based on a prediction frame ŝₜ, ŝₜ₊₁, ŝₜ₊₂, . . . , ŝₜ₊ₙ₋₁ of a previous time.

The time series prediction model 400 may predict satellite images ŝ₁₊₁, ŝₜ₊₂, . . . , ŝₜ₊ₙ; 450 for the prediction time t+1, t+2, . . . , t+n based on a plurality of satellite products Sₜ₋ₖ, . . . , Sₜ₋₂, Sₜ₋₁; 430.

Similarly to the inference step, in a training step, the encoder 410 may be trained based on the true frame at the corresponding time, and the forecaster 420 may be trained based on the prediction frame at the previous time.

However, there may be training inconsistency from the viewpoint of non-Markovian properties and long-term dynamics between the encoder 410 trained based on the true frame and the forecaster 420 trained based on the prediction frame. The training inconsistency may lead to inefficient optimization of a parameter.

As an additional exemplary embodiment, the encoder 410 may operate based on the true frame Sₜ₋ₖ, . . . , Sₜ₋₂, Sₜ₋₁; 430 at the corresponding time in the actual inference step, but may be trained based on both a prediction operation based on the true frame at the corresponding time and a prediction operation based on the prediction frame ŝₜ₋ₖ₊₁, . . . , ŝₜ₋₂, ŝₜ₋₁ at the previous time in the training step. Further, the forecaster 420 may perform the prediction based on the prediction frame ŝₜ, ŝₜ₊₁, ŝₜ₊₂, . . . , ŝₜ₊ₙ₋₁ at the previous time in the actual inference step, but may be trained based on the prediction operation based on the prediction frame at the previous time and a prediction operation based on a true frame Sₜ, Sₜ₊₁, . . . , Sₜ₊ₙ₋₁ at the previous time in the training step.

Unlike the inference step, in the training step, the encoder 410 additionally performs the prediction operation based on the prediction frame at the previous time, and the forecaster 420 additionally performs the prediction operation based on the true frame at the previous time, so the encoder 410 and the forecaster 420 may be trained to perform more accurate prediction. Specifically, through such an additional training operation, the training inconsistency between the encoder 410 that performs the operation based on the true frame and the forecaster 420 that performs the operation based on the prediction frame may be alleviated, and a harmonious interlocking operation may be implemented.

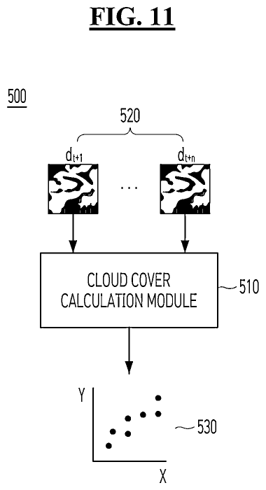

FIG. 11 is a diagram for describing a method for calculating cloud cover prediction information for a target region according to an exemplary embodiment of the present disclosure.

Referring to FIG. 11, the cloud cover calculation module 510 may obtain a prediction result dₜ₊₁, . . . , dₜ₊ₙ; 520 for cloud detection. The cloud cover calculation module 510 may calculate cloud cover prediction information of the target region based on the prediction result for the cloud detection in which each pixel is classified for each class.

Specifically, the cloud cover calculation module 510 may quantify the cloud cover for each class in the prediction result for the cloud detection, and determine pixel regions corresponding to an whole sky region, through a similarity analysis to the total cloud cover data of an automated surface observation system (ASOS).

The cloud cover calculation module 510 may calculate cloud cover prediction information of a target region by considering two parameters determined through the similarity analysis, i.e., i) the numerical value of cloud cover granted to an intermediate class of the prediction result for the cloud detection, and ii) the total number of pixels of the pixels regions corresponding to the whole sky region.

In the present disclosure, the method for calculating the cloud cover prediction information of the target region may be applied similarly to the method described with reference to FIG. 6.

For example, the cloud cover calculation module 510 may calculate each cloud cover according to the weight w of the ‘probably cloud’ class and the plurality of pixel regions corresponding to the candidate areas of the whole sky region.

The cloud cover calculation module 510 may determine a similarity between the cloud cover calculated in the prediction result for the cloud detection and total cloud cover data.

The cloud cover calculation module 510 may determine a weight for each class and an area of an whole sky region through similarity analysis.

The cloud cover calculation module 510 may calculate total cloud cover prediction information 530 of the target region by combining the cloud cover for each pixel for the target region based on the quantified cloud cover. In an output graph of the cloud cover calculation module 510, an x axis means the time and a y axis means the cloud cover prediction information. The cloud cover calculation module 510 may calculate the cloud cover prediction information 530 according to the time in the target region.

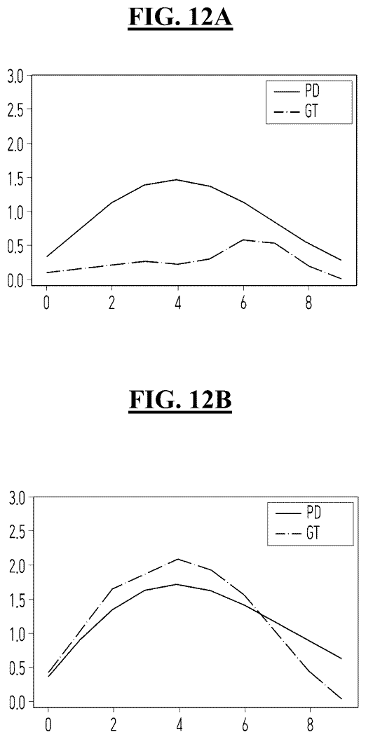

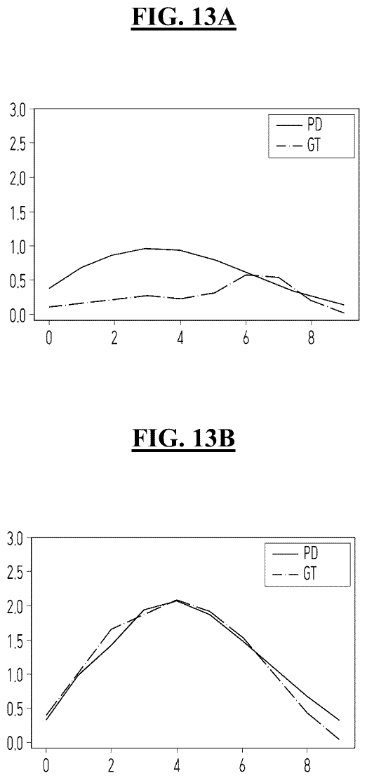

FIGS. 12A, 12B, 13A, and 13B are diagrams for comparing a performance difference of a solar radiation amount prediction model according to an exemplary embodiment of the present disclosure.

FIGS. 12A and 12B are diagrams illustrating a solar radiation amount predicted by the solar radiation amount prediction model when the cloud cover prediction information is not given. FIG. 12A is a graph of a cloudy day with a small solar radiation amount, and FIG. 12B is a graph of a clear day with a large solar radiation amount. A solid line PD represents a predicted solar radiation amount, and an alternated long and short dash line GT represents a true solar radiation amount.

In FIG. 12A, the solar radiation amount PD predicted by the solar radiation amount prediction model has a larger value than the true solar radiation amount GT. In FIG. 12B, the solar radiation amount PD predicted by the solar radiation amount prediction model does not follow a rapidly reduced solar radiation amount GT. Accordingly, when the cloud cover prediction information is not given, the solar radiation amount prediction model does not predict a solar radiation amount which increases or decreases due to the influence of the weather.

FIGS. 13A and 13B are diagrams illustrating a solar radiation amount predicted by the solar radiation amount prediction model when the cloud cover prediction information is given. FIG. 13A is a graph of a cloudy day with a small solar radiation amount, and FIG. 13B is a graph of a clear day with a large solar radiation amount. A solid line PD represents a predicted solar radiation amount, and an alternated long and short dash line GT represents a true solar radiation amount.

In each of FIGS. 13A and 13B, the solar radiation amount PD predicted by the solar radiation amount prediction model is similar to the true solar radiation amount GT. Accordingly, when the satellite image based cloud cover prediction information is applied to the solar radiation amount prediction model, the accuracy of the solar radiation amount prediction model may be increased.

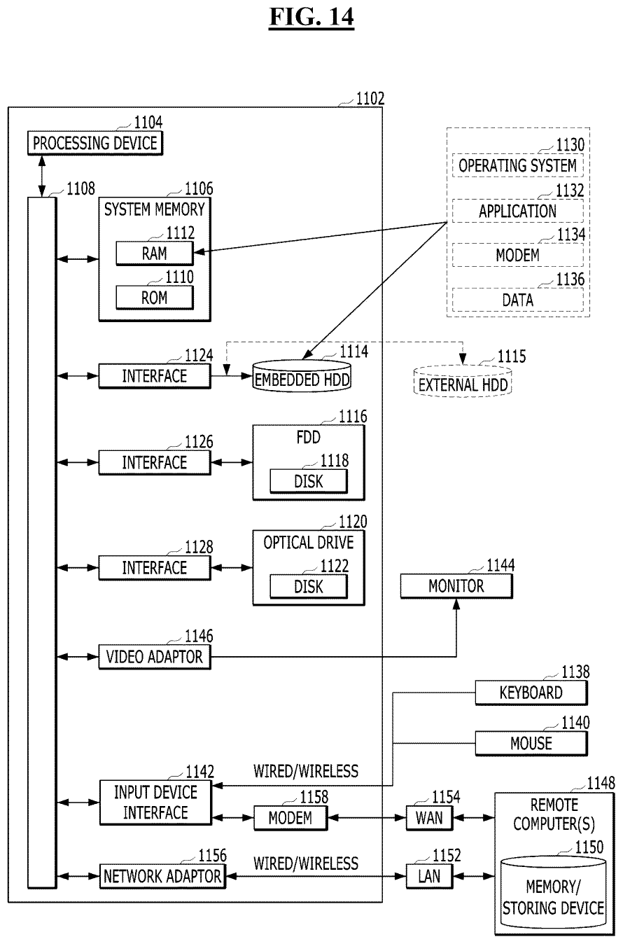

FIG. 14 is a simple and general schematic diagram illustrating an example of a computing environment in which the embodiments of the present disclosure are implementable.

The present disclosure has been described as being generally implementable by the computing device, but those skilled in the art will appreciate well that the present disclosure is combined with computer executable commands and/or other program modules executable in one or more computers and/or be implemented by a combination of hardware and software.

In general, a program module includes a routine, a program, a component, a data structure, and the like performing a specific task or implementing a specific abstract data form. Further, those skilled in the art will well appreciate that the method of the present disclosure may be carried out by a personal computer, a hand-held computing device, a microprocessor-based or programmable home appliance (each of which may be connected with one or more relevant devices and be operated), and other computer system configurations, as well as a single-processor or multiprocessor computer system, a mini computer, and a main frame computer.

The embodiments of the present disclosure may be carried out in a distribution computing environment, in which certain tasks are performed by remote processing devices connected through a communication network. In the distribution computing environment, a program module may be located in both a local memory storage device and a remote memory storage device.

The computer generally includes various computer readable media. The computer accessible medium may be any type of computer readable medium, and the computer readable medium includes volatile and non-volatile media, transitory and non-transitory media, and portable and non-portable media. As a non-limited example, the computer readable medium may include a computer readable storage medium and a computer readable transport medium. The computer readable storage medium includes volatile and non-volatile media, transitory and non-transitory media, and portable and non-portable media constructed by a predetermined method or technology, which stores information, such as a computer readable command, a data structure, a program module, or other data. The computer readable storage medium includes a RAM, a Read Only Memory (ROM), an Electrically Erasable and Programmable ROM (EEPROM), a flash memory, or other memory technologies, a Compact Disc (CD)-ROM, a Digital Video Disk (DVD), or other optical disk storage devices, a magnetic cassette, a magnetic tape, a magnetic disk storage device, or other magnetic storage device, or other predetermined media, which are accessible by a computer and are used for storing desired information, but is not limited thereto.

The computer readable transport medium generally implements a computer readable command, a data structure, a program module, or other data in a modulated data signal, such as a carrier wave or other transport mechanisms, and includes all of the information transport media. The modulated data signal means a signal, of which one or more of the characteristics are set or changed so as to encode information within the signal. As a non-limited example, the computer readable transport medium includes a wired medium, such as a wired network or a direct-wired connection, and a wireless medium, such as sound, Radio Frequency (RF), infrared rays, and other wireless media. A combination of the predetermined media among the foregoing media is also included in a range of the computer readable transport medium.

An illustrative environment 1100 including a computer 1102 and implementing several aspects of the present disclosure is illustrated, and the computer 1102 includes a processing device 1104, a system memory 1106, and a system bus 1108. The system bus 1108 connects system components including the system memory 1106 (not limited) to the processing device 1104. The processing device 1104 may be a predetermined processor among various commonly used processors. A dual processor and other multi-processor architectures may also be used as the processing device 1104.

The system bus 1108 may be a predetermined one among several types of bus structure, which may be additionally connectable to a local bus using a predetermined one among a memory bus, a peripheral device bus, and various common bus architectures. The system memory 1106 includes a ROM 1110, and a RAM 1112. A basic input/output system (BIOS) is stored in a non-volatile memory 1110, such as a ROM, an EPROM, and an EEPROM, and the BIOS includes a basic routing helping a transport of information among the constituent elements within the computer 1102 at a time, such as starting. The RAM 1112 may also include a high-rate RAM, such as a static RAM, for caching data.

The computer 1102 also includes an embedded hard disk drive (HDD) 1114 (for example, enhanced integrated drive electronics (EIDE) and serial advanced technology attachment (SATA))—the embedded HDD 1114 being configured for exterior mounted usage within a proper chassis (not illustrated)—a magnetic floppy disk drive (FDD) 1116 (for example, which is for reading data from a portable diskette 1118 or recording data in the portable diskette 1118), and an optical disk drive 1120 (for example, which is for reading a CD-ROM disk 1122, or reading data from other high-capacity optical media, such as a DVD, or recording data in the high-capacity optical media). A hard disk drive 1114, a magnetic disk drive 1116, and an optical disk drive 1120 may be connected to a system bus 1108 by a hard disk drive interface 1124, a magnetic disk drive interface 1126, and an optical drive interface 1128, respectively. An interface 1124 for implementing an outer mounted drive includes, for example, at least one of or both a universal serial bus (USB) and the Institute of Electrical and Electronics Engineers (IEEE) 1394 interface technology.

The drives and the computer readable media associated with the drives provide non-volatile storage of data, data structures, computer executable commands, and the like. In the case of the computer 1102, the drive and the medium correspond to the storage of random data in an appropriate digital form. In the description of the computer readable media, the HDD, the portable magnetic disk, and the portable optical media, such as a CD, or a DVD, are mentioned, but those skilled in the art will well appreciate that other types of computer readable media, such as a zip drive, a magnetic cassette, a flash memory card, and a cartridge, may also be used in the illustrative operation environment, and the predetermined medium may include computer executable commands for performing the methods of the present disclosure.

A plurality of program modules including an operation system 1130, one or more application programs 1132, other program modules 1134, and program data 1136 may be stored in the drive and the RAM 1112. An entirety or a part of the operation system, the application, the module, and/or data may also be cached in the RAM 1112. It will be well appreciated that the present disclosure may be implemented by several commercially usable operation systems or a combination of operation systems.

A user may input a command and information to the computer 1102 through one or more wired/wireless input devices, for example, a keyboard 1138 and a pointing device, such as a mouse 1140. Other input devices (not illustrated) may be a microphone, an IR remote controller, a joystick, a game pad, a stylus pen, a touch screen, and the like. The foregoing and other input devices are frequently connected to the processing device 1104 through an input device interface 1142 connected to the system bus 1108, but may be connected by other interfaces, such as a parallel port, an IEEE 1394 serial port, a game port, a USB port, an IR interface, and other interfaces.

A monitor 1144 or other types of display devices are also connected to the system bus 1108 through an interface, such as a video adaptor 1146. In addition to the monitor 1144, the computer generally includes other peripheral output devices (not illustrated), such as a speaker and a printer.

The computer 1102 may be operated in a networked environment by using a logical connection to one or more remote computers, such as remote computer(s) 1148, through wired and/or wireless communication. The remote computer(s) 1148 may be a work station, a computing device computer, a router, a personal computer, a portable computer, a microprocessor-based entertainment device, a peer device, and other general network nodes, and generally includes some or an entirety of the constituent elements described for the computer 1102, but only a memory storage device 1150 is illustrated for simplicity. The illustrated logical connection includes a wired/wireless connection to a local area network (LAN) 1152 and/or a larger network, for example, a wide area network (WAN) 1154. The LAN and WAN networking environments are general in an office and a company, and make an enterprise-wide computer network, such as an Intranet, easy, and all of the LAN and WAN networking environments may be connected to a worldwide computer network, for example, the Internet.

When the computer 1102 is used in the LAN networking environment, the computer 1102 is connected to the local network 1152 through a wired and/or wireless communication network interface or an adaptor 1156. The adaptor 1156 may make wired or wireless communication to the LAN 1152 easy, and the LAN 1152 also includes a wireless access point installed therein for the communication with the wireless adaptor 1156. When the computer 1102 is used in the WAN networking environment, the computer 1102 may include a modem 1158, is connected to a communication computing device on a WAN 1154, or includes other means setting communication through the WAN 1154 via the Internet. The modem 1158, which may be an embedded or outer-mounted and wired or wireless device, is connected to the system bus 1108 through a serial port interface 1142. In the networked environment, the program modules described for the computer 1102 or some of the program modules may be stored in a remote memory/storage device 1150. The illustrated network connection is illustrative, and those skilled in the art will appreciate well that other means setting a communication link between the computers may be used.

The computer 1102 performs an operation of communicating with a predetermined wireless device or entity, for example, a printer, a scanner, a desktop and/or portable computer, a portable data assistant (PDA), a communication satellite, predetermined equipment or place related to a wirelessly detectable tag, and a telephone, which is disposed by wireless communication and is operated. The operation includes a wireless fidelity (Wi-Fi) and Bluetooth wireless technology at least. Accordingly, the communication may have a pre-defined structure, such as a network in the related art, or may be simply ad hoc communication between at least two devices.

The Wi-Fi enables a connection to the Internet and the like even without a wire. The Wi-Fi is a wireless technology, such as a cellular phone, which enables the device, for example, the computer, to transmit and receive data indoors and outdoors, that is, in any place within a communication range of a base station. A Wi-Fi network uses a wireless technology, which is called IEEE 802.11 (a, b, g, etc.) for providing a safe, reliable, and high-rate wireless connection. The Wi-Fi may be used for connecting the computer to the computer, the Internet, and the wired network (IEEE 802.3 or Ethernet is used). The Wi-Fi network may be operated at, for example, a data rate of 11 Mbps (802.11a) or 54 Mbps (802.11b) in an unauthorized 2.4 and 5 GHz wireless band, or may be operated in a product including both bands (dual bands).

Those skilled in the art may appreciate that information and signals may be expressed by using predetermined various different technologies and techniques. For example, data, indications, commands, information, signals, bits, symbols, and chips referable in the foregoing description may be expressed with voltages, currents, electromagnetic waves, magnetic fields or particles, optical fields or particles, or a predetermined combination thereof.

Those skilled in the art will appreciate that the various illustrative logical blocks, modules, processors, means, circuits, and algorithm operations described in relationship to the embodiments disclosed herein may be implemented by electronic hardware (for convenience, called “software” herein), various forms of program or design code, or a combination thereof. In order to clearly describe compatibility of the hardware and the software, various illustrative components, blocks, modules, circuits, and operations are generally illustrated above in relation to the functions of the hardware and the software. Whether the function is implemented as hardware or software depends on design limits given to a specific application or an entire system. Those skilled in the art may perform the function described by various schemes for each specific application, but it shall not be construed that the determinations of the performance depart from the scope of the present disclosure.

Various embodiments presented herein may be implemented by a method, a device, or a manufactured article using a standard programming and/or engineering technology. A term “manufactured article” includes a computer program, a carrier, or a medium accessible from a predetermined computer-readable storage device. For example, the computer-readable storage medium includes a magnetic storage device (for example, a hard disk, a floppy disk, and a magnetic strip), an optical disk (for example, a CD and a DVD), a smart card, and a flash memory device (for example, an EEPROM, a card, a stick, and a key drive), but is not limited thereto. Further, various storage media presented herein include one or more devices and/or other machine-readable media for storing information.

It shall be understood that a specific order or a hierarchical structure of the operations included in the presented processes is an example of illustrative accesses. It shall be understood that a specific order or a hierarchical structure of the operations included in the processes may be rearranged within the scope of the present disclosure based on design priorities. The accompanying method claims provide various operations of elements in a sample order, but it does not mean that the claims are limited to the presented specific order or hierarchical structure.

The description of the presented embodiments is provided so as for those skilled in the art to use or carry out the present disclosure. Various modifications of the embodiments may be apparent to those skilled in the art, and general principles defined herein may be applied to other embodiments without departing from the scope of the present disclosure. Accordingly, the present disclosure is not limited to the embodiments suggested herein, and shall be interpreted within the broadest meaning range consistent to the principles and new characteristics presented herein.

What is claimed is:

1. A method for predicting a solar radiation amount by using a solar radiation amount prediction model, the method being performed by a computing device, the method comprising:
inputting weather information into a solar radiation amount prediction model performing time series prediction;
further inputting cloud cover prediction information into the solar radiation amount prediction model; and
predicting a solar radiation amount based on the weather information and the cloud cover prediction information by using the solar radiation amount prediction model.

2. The method of claim 1, wherein the inputting of the weather information into the solar radiation amount prediction model includes:
inputting the weather information into an encoder of the solar radiation amount prediction model, and
obtaining a context vector based on the weather information by using the encoder of the solar radiation amount prediction model.

3. The method of claim 2, wherein the inputting of the weather information into the solar radiation amount prediction model further includes:
inputting the obtained context vector into a decoder of the solar radiation amount prediction model.

4. The method of claim 3, wherein the further inputting of the cloud cover prediction information into the solar radiation amount prediction model includes:
further inputting the cloud cover prediction information into the decoder of the solar radiation amount prediction model.

5. The method of claim 4, wherein the predicting of the solar radiation amount based on the weather information and the cloud cover prediction information includes:
predicting the solar radiation amount based on the context vector and the cloud cover prediction information by using the decoder of the solar radiation amount prediction model.

6. The method of claim 1, wherein the weather information includes weather information at a previous time of a prediction time,
wherein the cloud cover prediction information includes cloud cover prediction information for the prediction time, and
wherein the predicting of the solar radiation amount based on the weather information and the cloud cover prediction information includes:
predicting a solar radiation amount for the prediction time.

7. The method of claim 6, wherein the further inputting of the cloud cover prediction information into the solar radiation amount prediction model includes:
concatenating the weather information at the previous time of the prediction time and the cloud cover prediction information for the prediction time, and inputting the concatenated information into a decoder cell corresponding to the prediction time among a plurality of decoder cells included in the decoder of the solar radiation amount prediction model.

8. The method of claim 1, wherein the cloud cover prediction information is cloud cover prediction information calculated based on a satellite image predicted by using a time series prediction model.

9. The method of claim 1, wherein the weather information includes weather observation data, and cloud cover information calculated based on a cloud detection result.

10. The method of claim 9, wherein the cloud cover information is cloud cover information calculated by quantifying a cloud cover for each class, and combining a cloud cover for each pixel for a target region based on the quantified cloud cover, in the cloud detection result in which each pixel is classified for the each class.

11. A computer program stored in a non-transitory computer-readable storage medium, wherein the computer program cause one or more processors to execute following operations for predicting a solar radiation amount by using a solar radiation amount prediction model when the computer program is executed by the one or more processors, the operations comprising:
an operation of inputting weather information into a solar radiation amount prediction model performing time series prediction;
an operation of further inputting cloud cover prediction information into the solar radiation amount prediction model; and
an operation of predicting a solar radiation amount based on the weather information and the cloud cover prediction information by using the solar radiation amount prediction model.

12. The computer program of claim 11, wherein the operation of inputting the weather information into the solar radiation amount prediction model includes:
an operation of inputting the weather information into an encoder of the solar radiation amount prediction model, and
an operation of obtaining a context vector based on the weather information by using the encoder of the solar radiation amount prediction model.

13. The computer program of claim 12, wherein the operation of inputting the weather information into the solar radiation amount prediction model further includes:
an operation of inputting the obtained context vector into a decoder of the solar radiation amount prediction model.

14. The computer program of claim 13, wherein the operation of further inputting the cloud cover prediction information into the solar radiation amount prediction model includes:
an operation of further inputting the cloud cover prediction information into the decoder of the solar radiation amount prediction model.

15. The computer program of claim 14, wherein the operation of predicting the solar radiation amount based on the weather information and the cloud cover prediction information includes:
an operation of predicting the solar radiation amount based on the context vector and the cloud cover prediction information by using the decoder of the solar radiation amount prediction model.

16. A computing device comprising:
at least one processor; and
a memory,
wherein the at least one processor is configured to:
input weather information into a solar radiation amount prediction model performing time series prediction,
further input cloud cover prediction information into the solar radiation amount prediction model, and
predict a solar radiation amount based on the weather information and the cloud cover prediction information by using the solar radiation amount prediction model.

17. The computing device of claim 16, wherein the at least one processor is further configured to:
input the weather information into an encoder of the solar radiation amount prediction model, and
obtain a context vector based on the weather information by using the encoder of the solar radiation amount prediction model.

18. The computing device of claim 17, wherein the at least one processor is further configured to:
input the obtained context vector into a decoder of the solar radiation amount prediction model.

19. The computing device of claim 18, wherein the at least one processor is further configured to:
further input the cloud cover prediction information into the decoder of the solar radiation amount prediction model.

20. The computing device of claim 19, wherein the at least one processor is further configured to:
predict the solar radiation amount based on the context vector and the cloud cover prediction information by using the decoder of the solar radiation amount prediction model.
